(19) United States
(12) Patent Application Publication
(10) Pub. No.: US 2025/0174460 A1
(43) Pub. Date: May 29, 2025

(54) ATOMIC SCALE FABRICATION OF DIAMOND QUANTUM COMPUTERS

(71) Applicants: Quantum Brilliance PTY LTD, Acton, Australian Capital Territory (AU); The Australian National University, Acton, Australian Capital Territory (AU)

(72) Inventors: Marcus DOHERTY, Acton, Australian Capital Territory (AU); Lachlan OBERG, Acton, Australian Capital Territory (AU); Cedric WEBER, Acton, Australian Capital Territory (AU); Tetiana SERGEIEVA, Acton, Australian Capital Territory (AU); Chris PAKES, Bundoora, Victoria (AU); Alex SCHENK, Bundoora, Victoria (AU); Alastair STACEY, Melbourne, Victoria (AU)

(21) Appl. No.: 18/715,414

(22) PCT Filed: Nov. 29, 2022
(86) PCT No.: PCT/AU2022/051425

§ 371 Date: May 31, 2024

(30) Foreign Application Priority Data
Dec. 3, 2021 (AU) 2021903915
Sep. 29, 2022 (AU) 2022902826

(51) Int. Cl. H01L 21/04; C30B 25/18; C30B 25/20; C30B 29/04; C30B 33/04; H01L 21/02

(52) U.S. Cl. CPC H01L 21/041; C30B 25/186; C30B 25/20; C30B 29/04; C30B 33/04; H01L 21/02527; H01L 21/0262

(57) ABSTRACT

This disclosure relates to a method for manufacturing multiple optically addressable qubits in diamond. The method comprises providing a diamond substrate with a passivated surface; removing passivation atoms from the passivated surface to create multiple de-passivated sites where the passivation atoms have been removed; exposing the multiple de-passivated sites to a nitrogen-containing compound to adsorb nitrogen at the multiple de-passivated sites of the diamond substrate; overgrowing the multiple de-passivated sites with diamond by chemical vapour deposition (CVD) at a diamond growth rate related to a temperature and a pressure, wherein diffusion or desorption of the nitrogen at the multiple de-passivated sites is avoided to incorporate the nitrogen into the diamond; converting the incorporated nitrogen into multiple nitrogen vacancies; and charging the multiple nitrogen vacancies with a negative charge.

### CROSS-REFERENCE TO RELATED APPLICATIONS

The present application claims priority from Australian Provisional Patent Application 2021903915 filed on 3 Dec. 2021 and Australian Provisional Patent Application 2022902826 filed on 29 Sep. 2022, the contents of which are incorporated herein by reference in their entirety.

### TECHNICAL FIELD

This disclosure relates to fabrication of diamond quantum computers, and in particular to fabricating nitrogen vacancies in diamond computers.

### BACKGROUND

In quantum computing, a qubit or quantum bit is the basic unit of quantum information. In a classical system, a bit can be in one state or the other. In contrast, quantum mechanics allows the qubit to be in a coherent superposition of both states simultaneously, a property that is fundamental to quantum mechanics and quantum computing.

Scalable architectures of diamond quantum microprocessors consist of arrays of processor nodes. Each processor node is comprised of an NV centre and a cluster of nuclear spins: the intrinsic nitrogen nuclear spin and between 0 and 4 13C nuclear spin impurities. The nuclear spins act as the qubits of the microprocessor, whilst the NV centres act as quantum buses that mediate the initialisation and readout of the qubits, and intra-and inter-node multi-qubit operations. Quantum computation is controlled via integrated electrical, optical, magnetic and classical computing systems.

One aspect of the realisation of the scalable architectures is the precision fabrication of arrays of NV centres that are separated by ˜5-10 nm with tolerance <1 nm. This precision is useful to magnetically-couple the electron spins of the NV centres so that they may mediate the inter-node multi-qubit operations. However, this precision fabrication is difficult to achieve using ‘top-down’ nitrogen (N) ion-implantation techniques owing to the limits of implantation mask fabrication and the scattering of implanted ions.

Any discussion of documents, acts, materials, devices, articles or the like which has been included in the present specification is not to be taken as an admission that any or all of these matters form part of the prior art base or were common general knowledge in the field relevant to the present disclosure as it existed before the priority date of each of the appended claims.

Throughout this specification the word “comprise”, or variations such as “comprises” or “comprising”, will be understood to imply the inclusion of a stated element, integer or step, or group of elements, integers or steps, but not the exclusion of any other element, integer or step, or group of elements, integers or steps.

### SUMMARY

A method for manufacturing multiple optically addressable qubits in diamond comprises:
providing a diamond substrate with a passivated surface;
removing passivation atoms from the passivated surface to create multiple de-passivated sites where the passivation atoms have been removed;
exposing the multiple de-passivated sites to a nitrogen-containing compound to adsorb nitrogen at the multiple de-passivated sites of the diamond substrate;
overgrowing the multiple de-passivated sites with diamond by chemical vapour deposition (CVD) at a diamond growth rate related to a temperature and a pressure, wherein diffusion or desorption of the nitrogen at the multiple de-passivated sites is avoided to incorporate the nitrogen into the diamond;
converting the incorporated nitrogen into multiple nitrogen vacancies; and
charging the multiple nitrogen vacancies with a negative charge.

It is an advantage that the low temperature and/or pressure and/or diamond growth rate avoids diffusion and/or desorption, which would occur when using CVD that has been optimised for maximum diamond growth. As a result, the method can be used to encapsulate nitrogen atoms that have been placed with atomic precision without affecting the placement of the nitrogen atoms.

In some embodiments, any one or more of the diamond growth rate, the temperature and the pressure is sufficiently low, to avoid diffusion or desorption of the nitrogen at the multiple de-passivated sites.

In some embodiments, the nitrogen at the multiple de-passivated sites is bonded to the diamond substrate by a covalent bond between the nitrogen and a carbon atom of the diamond substrate, the covalent bond being defined by a binding energy.

In some embodiments, any one or more of the diamond growth rate, the temperature and the pressure is sufficiently low to preserve the covalent bond.

In some embodiments, the relative rate of sample etching, controlled by sample temperature and reactive species, is significantly lower than the rate of growth, such that the nitrogen at the multiple de-passivated sites is not desorbed and does not diffuse prior to or during diamond overgrowth.

In some embodiments, the covalent bond is a sp³ bond.

In some embodiments, the method further comprises encapsulating the nitrogen at the multiple de-passivated sites by a protective layer.

In some embodiments, the method further comprises forming the protective layer by specialised chemical vapour deposition overgrowth, according to one or more option in Table 1.

In some embodiments, the method further comprises forming the protective layer by molecular beam epitaxy.

In some embodiments, the method further comprises preparing the diamond substrate to create atomically smooth patches on the diamond substrate.

In some embodiments, the method further comprises preparing the diamond substrate at a substrate surface misorientation angle relative to a nominal surface orientation, to create the atomically smooth patches.

In some embodiments, preparing the diamond substrate at the substrate surface misorientation angle comprises creating step edges that define the atomically smooth patches between adjacent step edges.

In some embodiments, overgrowing the diamond comprises growing a crystal lattice from the step edges.

In some embodiments, the substrate surface misorientation angle is between 0.1 and 3.4 degrees.

In some embodiments, converting the incorporated nitrogen into a nitrogen vacancy comprises carbon ion irradiation and annealing.

A method for manufacturing multiple optically addressable qubits in diamond comprises:
providing a diamond substrate with a passivated surface, wherein the diamond substrate includes a doped region to introduce delocalised charge carriers into the diamond substrate and/or provide grounding for injected carriers;
removing passivation atoms from the passivated surface to create multiple de-passivated sites where the passivation atoms have been removed, wherein removing of the passivation atoms comprises moving a tip of a scanning tunnelling microscope (STM) across the passivated surface at atomic precision and creating a pulsed voltage drop between tip and diamond surface to remove the passivation atoms;
exposing the multiple de-passivated sites to a nitrogen-containing compound to adsorb nitrogen at the multiple de-passivated sites of the diamond substrate;
overgrowing the multiple de-passivated sites with diamond;
converting the incorporated nitrogen into multiple nitrogen vacancies; and
charging the nitrogen vacancies with a negative charge.

It is an advantage that STM enables the removal of passivation atoms at atomic precision, which means that the ultimate location of the nitrogen will also be at atomic precision. Since the quantum properties change significantly with a change in the nitrogen location, the method enables quantum architectures with accurate and repeatable characteristics, such as inter-qubit coupling.

In some embodiments, the method further comprises preparing the diamond substrate to create atomically smooth patches on the diamond substrate.

In some embodiments, moving the tip of the STM further comprises imaging the passivated surface to locate the atomically smooth patches.

In some embodiments, the method further comprises preparing the diamond substrate at a substrate surface misorientation angle relative to a nominal surface orientation, to create the atomically smooth patches.

In some embodiments, preparing the diamond substrate at the substrate surface misorientation angle comprises creating step edges that define the atomically smooth patches between adjacent step edges.

In some embodiments, overgrowing the diamond comprises growing a crystal lattice from the step edges.

In some embodiments, the substrate surface misorientation angle is between 0.1 and 3.4 degrees.

In some embodiments, the method further comprises, after moving the tip of the STM and before exposing the de-passivated site to the nitrogen-containing compound, confirming the removal of the passivation atoms from the passivated surface using STM imaging.

In some embodiments, the method further comprises confirming the adsorption of the nitrogen-containing compound to the diamond substrate using STM imaging.

In some embodiments, confirming the adsorption of the nitrogen-containing compound further comprises confirming that the nitrogen-containing compound adsorbed to the diamond substrate has a desired orientation relative to the diamond substrate.

In some embodiments, (a) the diamond substrate has a {100} surface and the desired orientation is an orientation relative to the diamond substrate that provides four sp3 bonds across two adjacent surface dimers; or (b) the diamond substrate has a {111} surface and the desired orientation is an orientation relative to the diamond substrate that provides three sp3 bonds to three surface carbon atoms.

In some embodiments, the method further comprises desorbing, using STM, the nitrogen-containing compound from the de-passivated site upon confirming that the nitrogen-containing compound has an undesired orientation relative to the diamond substrate.

In some embodiments, removing the passivation atoms by the STM is performed at a pressure between 1×10−11 Torr and 1×10−9 Torr.

In some embodiments, removing the passivation atoms by the STM further comprises current pulses ranging from 1 ms to 10 ms with voltages ranging from 2.7 V to 7 V and currents ranging from 1 nA to 50 nA.

In some embodiments, overgrowing the de-passivated site with diamond is performed by chemical vapour deposition.

In some embodiments, converting the incorporated nitrogen into a nitrogen vacancy comprises carbon ion irradiation and annealing.

A method for manufacturing multiple optically addressable qubits in diamond comprises:
providing a diamond substrate with a passivated surface;
removing passivation atoms from the passivated surface to create multiple de-passivated sites where the passivation atoms have been removed;
exposing the multiple de-passivated sites to a nitrogen-containing compound comprising a reactive nitrogen group, to adsorb nitrogen from the reactive nitrogen group at the multiple de-passivated sites of the diamond substrate;
overgrowing the multiple de-passivated sites with diamond;
converting the incorporated nitrogen into multiple nitrogen vacancies; and
charging the nitrogen vacancies with a negative charge.

It is an advantage that exposing the de-passivated site to a nitrogen-containing compound does not destroy the passivation at non-exposed areas. This means the nitrogen is only adsorbed where the passivation atoms have been removed. This enables accurate implantation of nitrogen into the diamond which, in turn, enables repeatable fabrication of devices with desired quantum characteristics, such as inter-qubit coupling.

In some embodiments, the nitrogen of the reactive nitrogen group forms a bond with a carbon atom of the diamond substrate at the de-passivated site.

In some embodiments, the reactive nitrogen group is a functional group and is bonded to a non-reactive group.

In some embodiments, the non-reactive group comprises a hydrocarbon.

In some embodiments, adsorbing the nitrogen-containing compound at the de-passivated site further comprises removing the non-reactive group by post-exposure heating.

In some embodiments, post-exposure heating is performed at a temperature that (a) preserves the bond between the carbon atom of the diamond substrate at the de-passivated site and the nitrogen of the reactive nitrogen group; and (b) breaks the bond between the reactive nitrogen group and the non-reactive group.

In some embodiments, the nitrogen-containing compound is a nitrile.

In some embodiments, the nitrogen-containing compound is an aziridine.

In some embodiments, the nitrogen-containing compound comprises an aromatic ring.

In some embodiments, the nitrogen-containing-compound comprises a nitrogen atom bonded to three carbon atoms.

In some embodiments, the nitrogen forms a lone electronic pair.

In some embodiments, the nitrogen containing compound comprises three or four double carbon bonds.

In some embodiments, exposing the multiple de-passivated sites to the nitrogen-containing compound further comprises isotopic control of the adsorbed nitrogen to control a spin of the adsorbed nitrogen.

In some embodiments, the nitrogen-containing compound comprises a ¹³C isotope and exposing the multiple de-passivated sites to the nitrogen-containing compound comprises doping of the diamond substrate with the ¹³C isotope.

In some embodiments, the ¹³C isotope in the diamond substrate forms a qubit.

In some embodiments, when in use, the qubit formed by the ¹³C isotope performs quantum data operations and the nitrogen vacancies act as a quantum bus.

In some embodiments, the method further comprises confirming the adsorption of the nitrogen-containing compound to the diamond substrate using scanning tunnelling microscopy (STM) imaging.

In some embodiments, confirming the adsorption of the nitrogen-containing compound further comprises confirming that the nitrogen-containing compound has a desired orientation relative to the diamond substrate.

In some embodiments, the desired orientation is an orientation relative to the diamond substrate that provides four sp3 bonds across two adjacent surface dimers.

In some embodiments, the method further comprises desorbing, using STM, the nitrogen-containing compound from the de-passivated site upon confirming that the nitrogen-containing compound has an undesired orientation relative to the diamond substrate.

In some embodiments, the method further comprises preparing the diamond substrate to create atomically smooth patches on the diamond substrate.

In some embodiments, the method further comprises preparing the diamond substrate at a substrate surface misorientation angle relative to a nominal surface orientation, to create the atomically smooth patches.

In some embodiments, preparing the diamond substrate at the substrate surface misorientation angle comprises creating step edges that define the atomically smooth patches between adjacent step edges.

In some embodiments, overgrowing the diamond comprises growing a crystal lattice from the step edges.

In some embodiments, the substrate surface misorientation angle is between 0.1 and 3.4 degrees.

In some embodiments, overgrowing the de-passivated site with diamond is performed by chemical vapour deposition.

In some embodiments, converting the incorporated nitrogen into a nitrogen vacancy comprises carbon ion irradiation and annealing.

It is noted that optional features provided with respect to one of the methods above, are equally optional features of the other methods.

### BRIEF DESCRIPTION OF DRAWINGS

FIG. 1a illustrates multiple optically addressable qubits in diamond.

FIG. 1b illustrates a method for manufacturing multiple optically addressable qubits in diamond.

FIG. 2a illustrates the preparation of the diamond sample and surface.

FIG. 2b illustrates the atomically-precise diamond hydrogen desorption lithography using scanning tunnelling microscopy (STM).

FIG. 2c illustrates the exposure of the de-passivated site to a nitrogen-containing compound.

FIG. 2d illustrates the encapsulation of the nitrogen before diamond growth.

FIG. 2e illustrates the creation of a nitrogen-vacancy via ion implantation and annealing.

FIG. 3 illustrates a schematic of the diamond preparation for the atom-scale fabrication technique.

FIG. 4a illustrates the {100} H-terminated diamond surfaces following HDL.

FIG. 4b illustrates the {111} H-terminated diamond surfaces following HDL.

FIG. 5 illustrates a schematic of STM-based desorption.

FIG. 6 illustrates the expected adsorption configurations for acetonitrile on the cleanly-terminated {100} diamond surface.

FIG. 7 illustrates step-flow growth during chemical vapour deposition (CVD) being nucleated through an adsorbed C-C dimer on the new surface layer.

FIG. 8a illustrates one possible adsorbate configuration for aziridine on the bare {111} surface.

FIG. 8b illustrates further bonding of the adsorbate in FIG. 8a with a CH₂ group during CVD.

FIG. 8c illustrates the nucleus for new layer growth during {111} CVD overgrowth.

FIG. 9 illustrates XPS scans of the partially hydrogen terminated diamond surface following exposure of 1000 Langmuirs of acetonitrile at room temperature and subsequent thermal processing.

FIG. 10 illustrates simulated constant current (approximately 5 nA) STM images of the acetonitrile adsorbate in the A1, A2, and B1 configurations.

FIG. 11 illustrates examples of nitrogen containing aromatic compounds for industrial scaling of the methods disclosed herein.

### DESCRIPTION OF EMBODIMENTS

This disclosure provides a method for atom-scale fabrication of nitrogen-vacancy (NV) centres in diamond. “Atom-scale” in this context means that the location of the NV centres is determined on the length scale of atomic spacings. This is important because diamond quantum computers use the interaction between NV centres to enable operations on their qubits, and this interaction depends on the distance between qubits. The larger the interaction (closer the NV centres), the greater the speed and fidelity of the qubit operations. However, the NV centres should not be too close together because this impedes their stability and distinguishability. In some examples, even a change of distance of a few atomic lattice sites in the diamond crystal leads to a significant deterioration in the quantum operations. Therefore, it is an advantage of the disclosed method that it enables atomic precision to fabricate a multi-qubit quantum computer with reliable interaction between qubits.

In particular, this disclosure provides a technique for atom-scale fabrication of NV centres that enables the creation of the NV centre with atomic precision. This is important for its function in quantum computing. As discussed above, it is difficult with a “top-down” approach, such as by ion implantation into a diamond substrate, to achieve atomic-scale positioning of NV centres. More specifically, the energy needed for the ion to penetrate into the diamond is so high that the standard deviation of the location of the ion is about 5 nm. This is a lower bound for positioning accuracy and still too large for fabrication of functioning multi-qubit quantum computers.

Therefore, this disclosure provides a “bottom-up” approach, where the nitrogen is bonded to the diamond surface at atomic-scale precision and the diamond is then grown on top of the nitrogen. The bonding site is defined by atomic-scale hydrogen depassivation lithography (HDL) as disclosed herein. The HDL can be performed using a scanning tunnelling microscope (STM) or other techniques. Further, the disclosed atom-scale fabrication process uses multiple processes to inhibit the desorption and diffusion of the nitrogen defect and allows the attainment of atom-scale precision placement of NV centres.

In one example, the disclosed fabrication technique uses scanning tunnelling microscopy (STM) to find suitable sites on the diamond surface to introduce a nitrogen defect, depassivates a number of hydrogen-terminated sites with atomic precision, based on the requirements for the intended device, and verifies that those depassivated sites are created. It is noted that hydrogen passivation is used as an example herein, while other examples may use a surface that is passivated by other molecules or elements, such as fluorine. Further, other techniques than STM can be used to desorb the passivating hydrogen and therefore perform HDL, such as using electrons or x-rays to desorb the hydrogen.

The diamond surface is then exposed to a nitrogen-containing compound and the nitrogen in the nitrogen-containing compound adsorbs to the de-passivated site. If the nitrogen-containing compound is in a desired orientation with respect to the diamond surface, the covalent bond between the nitrogen and the carbon on the diamond surface can be sufficiently strong to withstand the volatile conditions of diamond overgrowth and prevent the migration and desorption of the nitrogen. STM imaging can confirm the orientation of the nitrogen-containing compound that is adsorbed to the diamond surface. If the nitrogen containing compound is incorrectly orientated, thermal desorption or other methods can be used to remove it. After introducing the nitrogen to the diamond sample, chemical vapour deposition (CVD) is performed at a sufficiently low temperature and low pressure. This allows diamond to be grown over the nitrogen without causing it to diffuse within the diamond sample or desorb from the surface. Other examples use molecular beam epitaxy (MBE) or atomic-layer deposition (ALD) instead of, or in addition to, CVD.

Additionally, the fabrication process may include the creation of a protective layer around the adsorbed nitrogen, which further prevents mitigation and desorption of the nitrogen in the diamond. Furthermore, atomic layer deposition (ALD) might provide a trigger to initiate the overgrowth with the deposition of a few mono-atomic carbon layers, due to its ability to deposit high quality and uniform materials with precise control of the layer thickness. The initiation of ALD growth on depassivated diamond can be a challenge due to the lack of out-of-plane active bonds, but ALD growth can occur on defect sites or grain boundaries where dangling bonds or functional groups are present. ALD can be performed on diamond with any of the following embodiments: 1) the use of seed-layers, such as self-assembled monolayers, 2) the creation of functional groups on the diamond surface by for example fluorine, ozone, and plasma treatments, and 3) tuning the underlying substrate to enhance nucleation. Finally, diamond overgrowth might also be achieved by molecular beam epitaxy with mass-selected carbon ions at low gas pressure in high vacuum, using for example evaporation of carbon-60 from effusion cell a molecular beam epitaxy reactor.

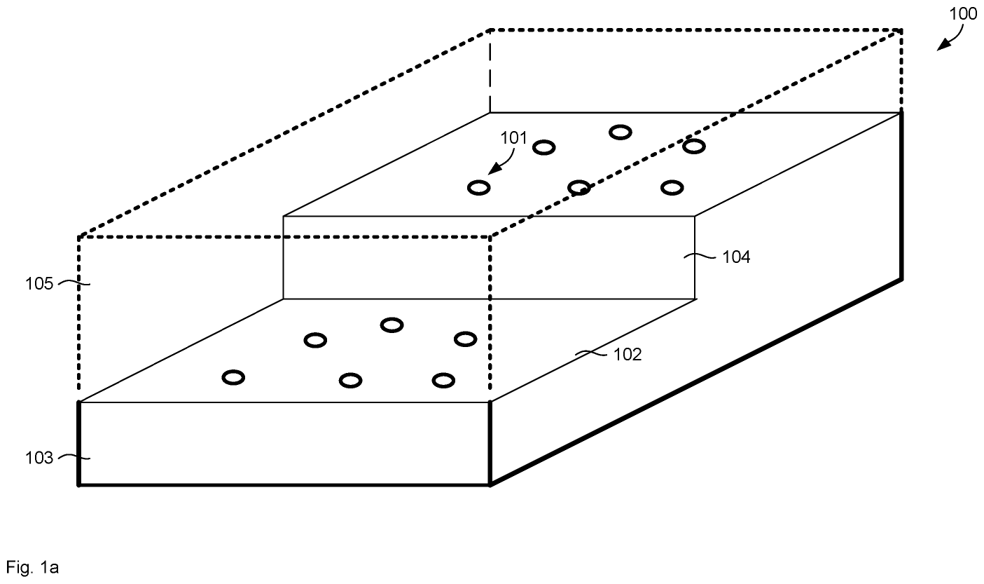

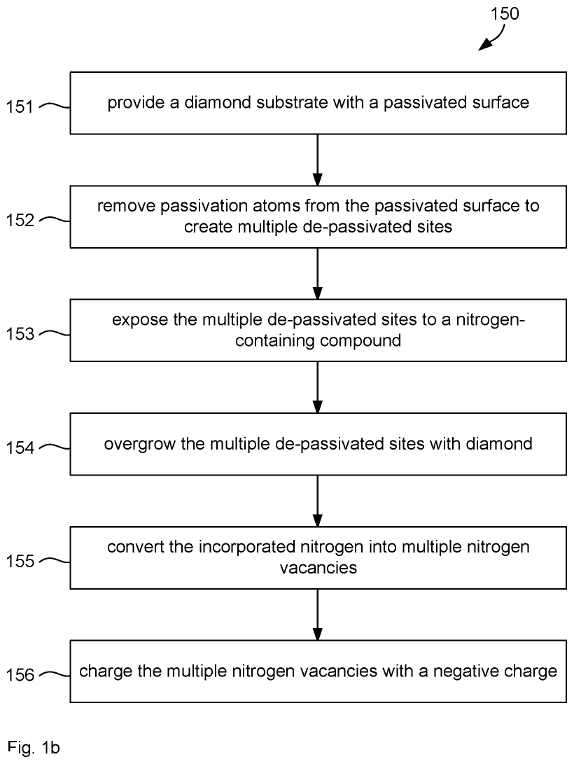

FIG. 1a illustrates multiple optically addressable qubits in diamond 100, also referred to as an array of qubits. The multiple optically addressable qubits 101 are created by placing Nitrogen on atomically flat surfaces 102 (referred to as “terraces”) on the surface of a diamond substrate 103 and are defined by a step edge 104 that is a boundary between adjacent terraces. Since the step edge 104 exists naturally due to a miscut angle, it is typically exactly one atom high. The nitrogen becomes incorporated into the diamond through diamond overgrowth 105 that is created using chemical vapour deposition (CVD) to form optically addressable qubits 101. It is noted that the step edge 104 is shown for illustrative purposes only, noting that after overgrowth the step edge 104 will not be present anymore as it is incorporated into the diamond crystal. The bold lines (dashed and solid) indicate the final device (including the qubits 101). The thin lines indicate the terraces and step edge 104 that are not present in the final device.

This also means that the optically addressable qubits 101 are not themselves on different terraces. This is because once the nitrogen is converted to a qubit, the terraces are not present anymore but integrated into the diamond. The end result is that qubits that originate from the nitrogen on different terraces will be at a slightly different height after overgrowth. Since the step height is only one atom, this different height should not reduce the functionality of the final device.

Further, the qubits 101 interact with each other to perform a quantum operation, thereby forming a quantum computer. In this regard, it is noted that, depending on the location of the qubits 101, qubits on different terraces interact with each other similar to qubits located on the same terrace. The qubits 101 are optically addressable because they are incorporated in diamond which transmits light. This is in contrast to other architectures, such as silicon, which is not transparent to light. In diamond, the qubits 101 can be addressed individually by a laser in combination with magnetic field gradients and frequency-selective microwave pulses. Therefore, there may also be a microwave source, a magnet and a photodetector (not shown) to control and readout the quantum information.

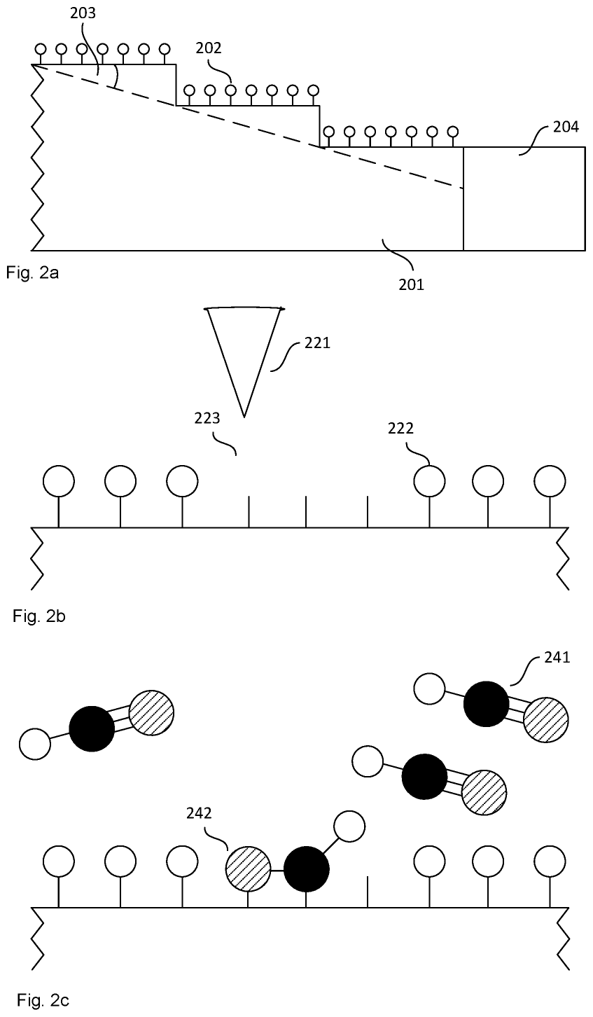

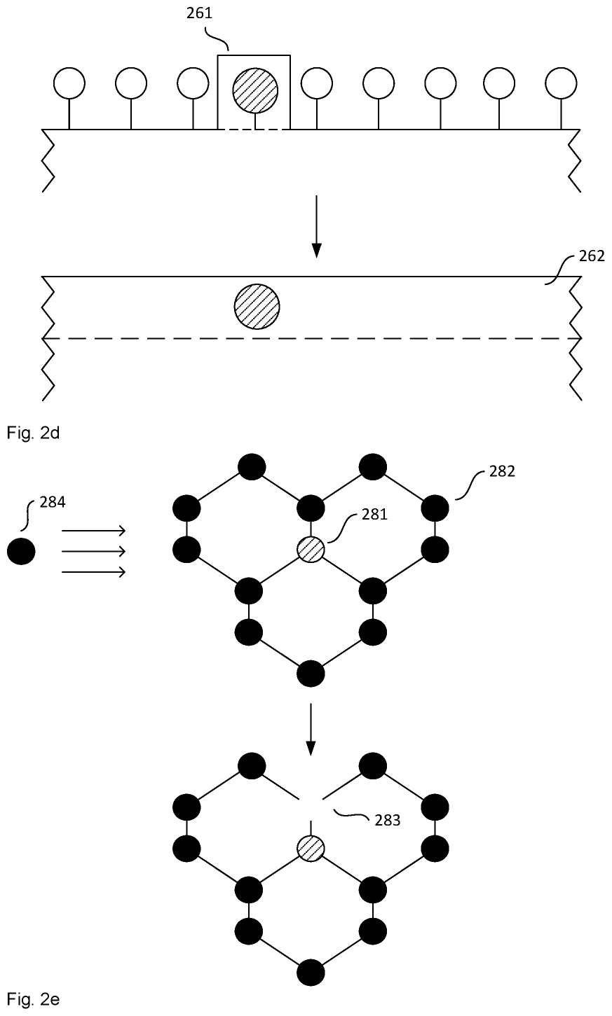

FIG. 1b illustrates a method 150 for atom-scale fabrication of nitrogen-vacancy (NV) centres in diamond. The fabrication process comprises providing 151 a diamond substrate with a passivated surface, and removing 152 hydrogen atoms from the passivated surface to create a de-passivated site where the hydrogen atoms have been removed. The next step is exposing 153 the de-passivated site to a nitrogen-containing compound to adsorb nitrogen at the de-passivated site of the diamond substrate, and overgrowing 154 the de-passivated site with diamond by CVD. After diamond overgrowth with CVD, the fabrication process comprises converting 155 the incorporated nitrogen into a nitrogen vacancy (either by an explicit processing step or implicitly by overgrowing the diamond as outlined below), and charging 156 the nitrogen vacancy with a negative charge. It may be possible that the incorporated nitrogen is converted into a NV centre during the CVD overgrowth, in which case, step 154 and 155 are performed in the same fabrication step. The fabrication process can be described in five sequential stages and these steps will be described in more detail with reference to FIGS. 2a-2e.

FIG. 2a illustrates the preparation of the diamond sample and surface corresponding to step 151 in method 150. In this stage, a diamond sample 201, including the diamond surface, is prepared, so it is compatible with STM and the associated hydrogen desorption lithography (HDL). The process uses sufficiently large, atomically smooth, and ordered patches of atoms (known as terraces) of, for example, 10 nm×10 nm and low surface roughness as an appropriate site for the N defect. In some examples, the minimum size of the patches is three dimers wide, that is 1.5 nm. The carbon atoms on the surface of the terraces are hydrogen 202 terminated and there is a low density of non-terminated sites across the entire diamond surface. The production of this surface uses an atomically smooth surface, which means there is a relatively small misorientation angle 203 relative to a nominal surface orientation. This angle may be relative to a nominated low index crystal plane, such as {100} or {111}. In one example, this misorientation angle is only applied for the part of the surface on which the NVs are being made (local miscut), rather than the entire sample surface (global miscut)—which could have a different average misorientation angle. The diamond sample 201 also includes a doped region 204, that provides mobile charge carriers to the diamond sample 201, which enables the implementation of STM.

FIG. 2b illustrates the atomically-precise diamond HDL using scanning tunnelling microscopy corresponding to step 152 in method 150. The tip 221 of the scanning tunnelling microscope is used to desorb hydrogen 222 atoms from the diamond surface, which leaves a de-passivated carbon site 223. STM is used, in conjunction with the de-passivation process, to both identify the adsorption site and verify successful molecular adsorption by using the STM imaging mode. The de-passivation process leaves an unpaired (i.e. unbonded) valence electron, which is highly reactive and readily forms a bond with a nitrogen atom from a nitrogen-containing molecule. Therefore, the de-passivated sites may also be referred to as “reactive sites”.

After depassivation and before nitrogen exposure, carbon atoms on the depassivated {111} surface have a dangling sp³ bond. On the depassivated {100} surface, the orbitals may not be purely sp² or sp³, and may not strictly be dangling because the two depassivated orbitals of a dimer form a weak bond. For completeness, it is noted that on both surface orientations (and other orientations) the depassivated site is highly reactive.

FIG. 2c illustrates the exposure of the de-passivated site to a nitrogen-containing compound corresponding to step 153 in method 150. After de-passivation of the terminal hydrogen, the diamond substrate is exposed to a nitrogen-containing compound 241. The high reactivity of the de-passivated carbon site causes the nitrogen atom of the nitrogen-containing compound 241 to chemically adsorb to the de-passivated site. Ideally, the nitrogen-containing compound adsorbed to the diamond surface 242 is strongly bonded in order to withstand the volatile conditions of later CVD for diamond overgrowth. Undesired adsorbates/adsorbate configurations can be desorbed using post-exposure heating of diamond sample after exposure to the nitrogen-containing compound 241. Adsorption of the nitrogen-containing compound to the diamond surface 242 can be confirmed through STM imaging.

FIG. 2d illustrates the encapsulation of the nitrogen before diamond growth corresponding to step 154 in method 150. The encapsulation of the nitrogen 261 means subsequent diamond overgrowth 262 can occur without causing migration or desorption of the nitrogen. There are two methods for encapsulating the nitrogen: specialised CVD overgrowth and in-situ growth of a molecular beam epitaxy (MBE) diamond “capping” layer. Both methods introduce a protective layer with the thickness of one or more (1-100) atoms, which protect the nitrogen during etching with reactive gas species (such as atomic hydrogen, or carbon-containing species)—and thermal desorption. The layer may not be a complete ‘layer’ (i.e. the nitrogen can be located in a hole in the ‘protective layer’).

FIG. 2e illustrates the conversion of nitrogen to a nitrogen-vacancy via radiation damage and annealing. corresponding to step 155 in method 150. Ion implantation, electron beam and pulsed laser are examples of radiation damage mechanisms. The nitrogen defect 281 in the diamond structure 282 is transformed into a nitrogen-vacancy (NV) centre 283 through carbon ion irradiation and annealing 284. There is a non-zero probability that the adsorbed N is converted to a NV centre 283 instead of a substitutional N defect during CVD overgrowth. Conversion of the nitrogen to a NV centre may occur during growth (i.e. this may be a feature of {111} growth, which also leads to the outcome of alignment). So step 5 may occur simultaneously with step 4 if that method of growth is applied. The NV centre is converted to a NV⁻ centre (i.e. a negatively charged NV centre) by the presence of nearby electron donors, which can be enhanced by the application of an external voltage in the proximity of the NV centre. In some examples, the device design may include an electrode to further stabilise the charge state.

The diamond surface may be sourced with one of two surface orientations: {100} surface orientation and {111} surface orientation. The notation {100} and {111} are Miller Indices, which indicates the plane of the diamond unit cell that the surface carbon atoms lie.

The important process steps for each stage 151-156 above, along with relevant technical details and scientific justification, will now be described.

### Step 1: Preparation of the Diamond Sample and Surface

The outcome of Step 1 (item 151 in method 150) is preparation of a diamond sample (including surface) that is compatible with HDL and subsequent steps in the fabrication process.

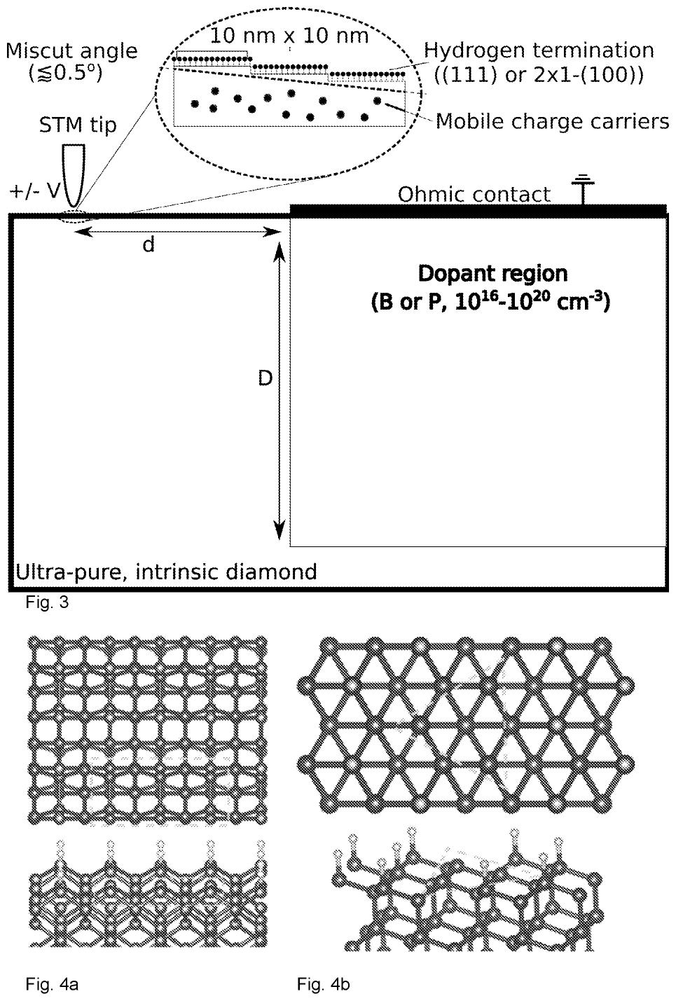

FIG. 3 illustrates a schematic of the diamond preparation for the atom-scale fabrication technique. The atom-scale fabrication technique uses the following:

A single crystal diamond substrate, with a {100} or {111} surface orientation is provided. The {100} and {111} surface orientations are compatible with Step 3. Both surfaces allow for the adsorption of nitrogen-containing molecules. While examples herein relate to the surface preparation and chemistry of the {100} surface, the {111} surface may be more compatible with the atom-scale fabrication process due to its favourable reaction chemistry (c.f., Step 3 as illustrated in FIG. 2c), stability and preferential alignment of NV defect axes during overgrowth (c.f., Step 4 as illustrated in FIG. 2d).

Atomically flat terraces of 10 nm×10 nm (at least 1.5 nm wide) and low surface roughness can be achieved by growth or etching. The atom-scale fabrication process is performed by atomic manipulation of hydrogen-terminated diamond surfaces, that is, the fabrication has a location accuracy on the scale of individual atoms. The surfaces present sufficiently large, atomically smooth, and ordered patches (known as terraces). The production of such a surface uses controlled, and low substrate surface misorientation angle relative to a nominal surface orientation (also referred to as “surface miscut angle” in the scientific literature and industry), as well as careful ex-situ preparation. Performing HDL in a reliable manner uses atomically flat terraces on the scale of 10 nm×10 nm, for example, corresponding to a maximum surface miscut of 0.5 degrees. There may also be a minimum miscut angle of 0.1 degrees, for example, to provide sufficient step edges for crystal growth. The miscut angle may also depend on the surface orientation (i.e. {100} or {111}). In some examples, the miscut angle is between 0.1 and 3.4 degrees.

The direction of the miscut also influences the shape and structure of the terraces. Low roughness (i.e., each terrace is flat, with few defects) is used because surface defects make precise STM imaging and associated HDL difficult. Preparing the diamond surface at the surface misorientation angle will also produce step edges that act as borders between adjacent terraces. These step edges will typically have a height of exactly one atom. These step edges also provide control of the CVD diamond overgrowth as the diamond growth emanates from the step edges.

It is noted that the methods disclosed herein can be used to manufacture multiple qubits. That is, the HDL removes hydrogen atoms at multiple sites and each of these multiple sites is later used for creation of one qubit. The interaction between these qubits depends on the distance between the de-passivated sites and can be engineered to suit a particular quantum computing application. As such, there may be more than one depassivated site for a nitrogen atom per terrace, provided the sites are spaced appropriately, such that later formed qubits will also interact with qubits form by nitrogen on a different terrace. For example, there may be 2×2 qubits with 5 nm spacing from nitrogen on a 10 nm×10 nm terrace or 10×10 qubits with 5 nm spacing on from nitrogen on a 100 nm×100 nm terrace. In one example, the distance between the qubits is 5 nm with a tolerance of +/−1 nm.

The disclosed method provides for creation of a diamond surface that is hydrogen terminated, ideally perfectly, but can tolerate a low density of uncontrolled/random/parasitic non-terminated sites on the diamond surface. Uncontrolled/random/parasitic non-terminated sites on the surface act as erroneous adsorption sites for nitrogen-containing molecules. Hydrogen termination is known to provide an effective resist for lithography. The process of hydrogen-termination with a microwave plasma is one part of a multiple step process that yields a surface with an appropriate terraced morphology for later steps. The remaining steps in this multiple step process are polishing, etching of the surface and/or growth on the surface.

The disclosed method uses high purity diamond with less than <1 ppb N content and <0.3% 13C isotopes. NV centre coherence time scales with diamond purity and so does quantum operation performance. Nitrogen defects can erroneously be converted into NV centres during annealing, producing background signals in fabricated quantum processors that reduce qubit initialisation and readout performance.

The method uses a doped region to produce n or p doping with activated defects concentrations of 10¹⁶-10²⁰ cm⁻³. Activated defects are defined as those which act as either donors or acceptors. Two possible dopants are substitutional boron (p-type) or substitutional phosphorous (n-type). This doped region will introduce delocalised charge carriers into the diamond substrate. These delocalised charge carriers enable the implementation of STM because they provide for an electric current through the diamond.

The doped region is sufficiently distant (on the order of micrometres, e.g., 1-100 μm) from the fabrication point to prevent NV decoherence effects in the final device, which limit quantum computing performance. This is limited by the sharpness of the interface between the doped and intrinsic regions. As indicated in FIG. 3, the STM operation (in conventional imaging modes) uses a depth of the doping region (D) that is greater than the distance between the fabrication point and doping region (d). In STM operation (hot electron injection imaging modes, c.f., Step 2 as illustrated in FIG. 2b) d can be up to approximately 100 μm.

The method creates low resistance contact on the diamond surface above the doped region. For example, an ohmic contact using palladium. The contact provides a source or sink for charged carriers during scanning tunnelling microscopy.

The procedure for this step is as follows:
1. Acquire undoped, high purity, single-crystal diamond sample with {100} or {111} surface orientation from supplier.
2. ‘Surface treatment with a combination of mechanical polishing, chemo-mechanical polishing (CMP), reactive-ion etching (RIE) and wet-chemistry cleaning, such as acid cleaning, to achieve a threshold root mean square (RMS) and miscut angle while minimizing sub-surface damage.
3. Post-polishing cleaning step.
4. Patterned dopant implantation through a mask and subsequent annealing to produce n-type or p-type doping (10¹⁶-10²⁰ cm⁻³ of Activated dopants). This may also be achieved by lithography and CVD.
5. Cleaning, such as acid cleaning.
6. Creation of atomically flat terraces using hydrogen plasma or adding carbon in the plasma, with multiple plasma recipe steps, to ensure a high-quality surface. Other plasma additions, such as argon/oxygen/nitrogen/fluorine, may also be used.
7. Hydrogen plasma treatment to realise near unity hydrogen surface coverage.
8. Fabrication of a low-resistance contact pad on the diamond surface above the doped region using in-vacuum electron-beam evaporation.

There exists a close relationship between miscut of the diamond surface and the growth morphology of CVD diamond. Therefore, there may be a trade-off between the geometrically limited maximum terrace size and CVD growth morphology. The miscut angle is optimised in order to ensure adsorbed species do not undergo desorption during CVD growth.

In some experiments, the example preparation protocols produce typical average terrace widths of 3 nm, with isolated 10 nm individual terraces. Further optimisation of surface processing techniques are used to produce terraces with an average size of 10 nm×10 nm.

The preparation of the {111} diamond surface may also include flattening of the surface via a thermochemical reaction process. This etching process can be used to produce {111} diamond surfaces that exhibit a roughness of 0.3 nm over 10 to 15 mm length scales. The process involves:
Acid cleaning the {111} diamond substrate.
Deposition of a transition metal (e.g. Ni, or NiCr) film of thickness 500 nm on the {111} diamond substrate via electron beam evaporation.
Annealing the substrate at high temperature (900 C) in a quartz tube furnace in a water rich environment at atmospheric pressure, by bubbling nitrogen gas through water and flowing it at 10 sccm through the tube.
Acid cleaning the substrate to remove residue material
Repeating the process until the desired surface is achieved.

### Step 2: Hydrogen Desorption Lithography

Hydrogen desorption lithography (HDL) with a STM tip, achieved through a sequence of voltage pulses, is the controlled and deterministic de-passivation of single atomic sites at the hydrogen terminated diamond surface (i.e. at atomic-scale precision). De-passivated carbon sites on the surface possess an unpaired valence electron in an unbonded sp³ configuration (also termed as a “dangling” bond). The unpaired electrons are highly reactive sites for molecular adsorption, readily forming bonds with incident N-containing molecules (c.f., Step 3 as illustrated in FIG. 2c). In contrast, the hydrogen passivated diamond surface is largely unreactive due to the strong C—H bond energy.

The proposed specifications for fabricating a single NV centre are as follows. For {100} diamond, a patch of six adjacent hydrogen atoms is removed across three adjacent dimers, determined based on theoretical calculations with likely candidate nitrogen-containing molecules. For {111} diamond, a patch of three adjacent hydrogen atoms is removed which are arranged in a triangle.

FIG. 4a illustrates the {100} H-terminated diamond surfaces following HDL. FIG. 4b illustrates the {111} H-terminated diamond surfaces following HDL. The resulting cleanly-terminated patch is thermally stable and operates as an adsorption site for a nitrogen-containing molecule.

The above specifications describe the minimum amount of lithography needed to fabricate a single NV centre with lattice-site precision. Even if the de-passivated area is larger, nitrogen-containing molecules are still able to adsorb to the surface with near-identical chemistry as presented in Step 3.

STM imaging identifies the adsorption site and verifies successful molecular adsorption. Conventional STM imaging on diamond uses boron doping to realise p-type conductivity throughout the sample. However, the presence of dopants near the fabrication site is undesirable as they introduce decoherence effects in the final device. Hence, STM imaging of the fabrication site is performed on intrinsically insulating (i.e., locally un-doped) diamond. There are two methods for achieving this: (1) resonant electron injection, and (2) conventional imaging using a nearby doped contact region.

Resonant electron injection is achieved by injecting electrons from the STM tip into the diamond surface through a standing-wave resonance established in the vacuum gap between the tip and the sample. The energy of the resonant state varies with the surface potential at the site of the tip. Therefore, when the tip is biased at a fixed voltage, the injection (tunnelling) current is modulated by local changes in the surface potential as the tip is scanned across the surface. This permits imaging of the surface to identify a suitable site to perform lithography and imaging of the site, subsequent to lithography, to verify desorption of hydrogen.

Conventional STM imaging may also be achievable on an insulating surface by drawing charge carriers from a heavily n or p-doped region below an ohmic contact which is located nearby the fabrication point. Since the doped region is near the fabrication point, the charge carriers can be drawn in to use for STM imaging. Thermal ionisation of the dopants creates delocalised carriers, which localise underneath the STM tip when the tip is appropriately biased. The presence of carriers permits conventional STM imaging on the insulating surface through creating a substantial voltage drop between the STM tip and the surface and providing an unoccupied/occupied density of states. If n-type doping is used, then the same dopant region can be used to stabilise the NV charge state during device operation. In one example, conventional imaging is performed in the limit D>>d as shown in FIG. 3.

The procedure for this step is as follows:
1. Introduce hydrogen-terminated diamond to an ultrahigh vacuum environment which contains a STM and appropriate sample preparation tools.
2. Remove atmospheric contamination and adventitious carbon using in situ annealing processes, such as a 450 C anneal for 1 hour.
3. Use STM imaging mode (resonant injection or conventional) to identify suitable terrace (10 nm×10 nm) for lithography.
4. Position STM tip above sites where hydrogen desorption is desired and perform current/voltage pulsing until hydrogen has been removed. Repeat for all hydrogen atoms at desired depassivated sites.
5. Verify hydrogen has been desorbed using STM imaging mode, indicated by the presence of a localised dangling bond feature.

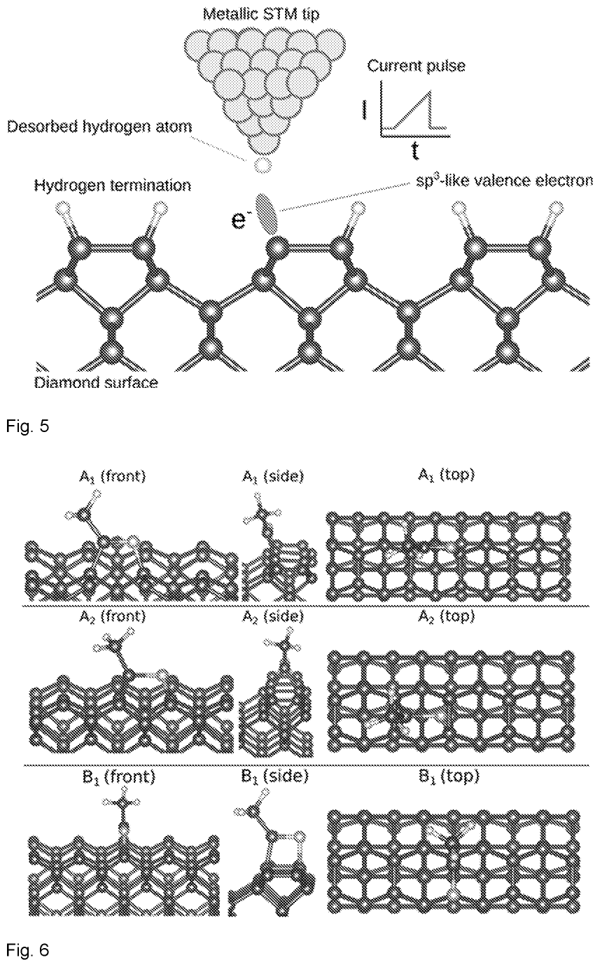

FIG. 5 illustrates a schematic of STM-based desorption. STM-based HDL on a H terminated diamond surface uses four parameters: the tip radius, the tunnelling current (dependent on bias voltage and tip height), and the tunnelling duration, as well as precision control of tip location. In particular, greater positional accuracy and precision, such as better than 1-2 atomic sites, can be obtained using sharper tips. The tip radius may be no greater than 1 nm.

Lithography in boron-doped diamond may be performed at a pressure of below 1×10⁻⁹, such as 2×10⁻¹¹ Torr. Hydrogen de-passivation in diamond may be performed with current pulses in the range of 1 ms to 10 ms, with voltages ranging from 2.7 V to 7 V and currents ranging from 1 nA to 50 nA.

### Step 3: Exposure to a Nitrogen-Containing Molecule

Step 3 (item 153 in method 150) may follow immediately after Step 2 in-situ. The desired outcome is the chemical adsorption of a single N containing molecule on the de-passivated sites produced using HDL. Ideally, the adsorbed molecule possesses a strong covalent bond to the surface (≳1 eV binding energy), with the nitrogen part of the molecule being directly bound to one or more of the depassivated sites. This is in order to withstand the volatile (high temperature/high particle flux) conditions of CVD during overgrowth (c.f., Step 4 as illustrated in FIG. 2d).

In some examples, a nitrogen-containing compound is used that comprises molecules which have been synthesised with a specific nitrogen isotope. This provides a choice between spin-1 and spin-1/2 qubit systems, which have different advantages and disadvantages for different roles. There also exists the possibility of seeding C qubits during Step 3 by synthesising the molecules using ¹³C and/or ¹⁴N or ¹⁵N precursors. The deliberate inclusion of isotopes within the molecule allows for fabrication of additional qubits associated with each NV centre. In an example, by engineering the position of ¹³C isotopes within the nitrogen-containing molecule, their position on the diamond surface can be deterministically controlled through adsorption chemistry. Following overgrowth, ¹³C qubits can therefore be positioned relative to the fabricated NV centre with atom-scale precision.

### {100} Surface

FIG. 6 illustrates the expected adsorption configurations for acetonitrile on the cleanly-terminated {100} diamond surface. Different classes of molecules may be suitable for adsorption depending on the surface geometry. For the {100} geometry, the surface may be exposed to a molecule containing a nitrile group (—CN). In an example, the molecule is hydrogen cyanide (HCN) or acetonitrile (C₂H₃N) but other molecules with a nitrile group should also perform well since, in the desired configurations, the nitrile group is what determines the reaction with the diamond surface. So it should not be relevant, which form the remainder of the molecule takes.

Quantum chemistry calculations on the two example molecules predict that the nitrile group can adsorb to the de-passivated surface in one of two orientations, parallel to the dimer rows (denoted A1) or perpendicular to them (denoted B1). For the A1 adsorbate, it is energetically feasible and favourable for a second surface reaction to occur in which the acetonitrile molecule repositions into the centre of the dimer, termed A2.

Similar bonding occurs for larger molecules which also possess a nitrile functional group. This is because the nitrile group is the active bonding region of the molecule, and other components of the molecule may not participate in bonding if they are not chemically reactive. The active bonding region can also be considered as a reactive nitrogen group, as it is the component of the molecule that contains the nitrogen and introduces the nitrogen to the diamond substrate by reacting to the “dangling” bond at the de-passivated site. The remaining components of the molecule form a non-reactive group that is bonded to the reactive nitrogen group. In an example, the number of single bonded carbons attached to the nitrile group in an alkane chain could be made arbitrarily large as they are unreactive with the diamond surface. Therefore, most molecules with a nitrile group (and no additional functional groups) bond to the {100} surface in the manner described above.

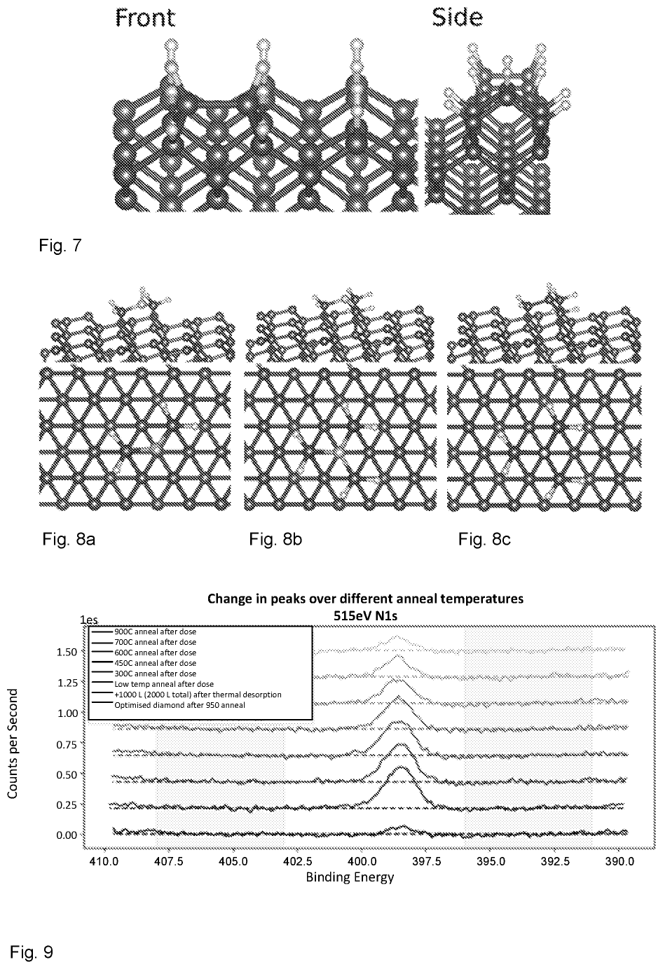

FIG. 7 illustrates step-flow growth during CVD being nucleated through an adsorbed C—C dimer on the new surface layer. Due to its geometric and electronic similarities with known structures of diamond layer growth, the A2 adsorbate configuration is desired for Step 4. Step-flow growth during CVD is nucleated through an adsorbed C—C dimer on the new surface layer. The A2 adsorbate possesses geometric similarities to the adsorbed dimer, in particular four sp³ bonds across two adjacent surface dimers. Therefore, the A2 adsorbate may be efficiently incorporated into the bulk diamond structure.

### {111} Surface

Atom-scale fabrication on the {111} surface may be desirable, as NV centres are naturally aligned along a common spin axis during CVD growth. The alignment of the centres is desirable for the function of the quantum computing device.

Similar to the case of {100} diamond, it may be advantageous to use a molecular adsorbate with a geometric and chemical resemblance to structures observed during CVD growth. Primarily, this is in order to enable incorporation of the nitrogen into a subsequently grown encapsulation layer. Possible candidates for {111} diamond which fit these requirements include aziridines and indolizine.

FIG. 8a illustrates one possible adsorbate configuration for aziridine on the bare {111} surface. FIG. 8b illustrates further bonding of the adsorbate in FIG. 8a with a CH₂ group during CVD. FIG. 8c illustrates the starting point for new layer growth during {111} CVD overgrowth. The aziridine functional group consists of a nitrogen and two carbon atoms bonded together in a triangular geometry. Due to the high strain of this molecular geometry, aziridines are highly reactive. For the case of the simplest aziridine (which is also called “aziridine”, (CH₂)₂NH), quantum chemistry calculations demonstrate that the molecule may adsorb to the {111} surface in the manner depicted in FIG. 8a. During CVD overgrowth, further bonding with a CH₂ group may lead to the structure depicted in FIG. 8b, a structure bears strong geometric and chemical similarities to the FIG. 8c, believed to be the starting point for new layer growth during {111} CVD overgrowth.

Other potential candidates for adsorption on the {111} surface include indolizine and molecules containing an isocyanide functional group. As with nitriles, molecules which possess only aziridine and isocyanide functional groups should bond to the {111} surface in an analogous manner to all other molecules which possess only that functional group. Other examples include the use of pyridine derivatives, which may be more practical to use.

The procedure for this step is as follows:
1. Expose surface to nitrogen containing molecule (the candidates above or other molecules) under UHV conditions at temperatures which allow molecular adsorption.
2. Post-exposure heating of sample to desorb undesired adsorbates/adsorbate configurations.
3. Confirm adsorption of molecule using STM in imaging mode. If not in STM (i.e. lithography performed using electrons/x-rays or other forms of lithography), rely on non-determinism of the chemical process.
4. Repeat step 1 to 3, until the molecule is successfully adsorbed.

Both the nitrile functional group and the aziridine functional group in their corresponding compound groups act as the reactive nitrogen group in this process. These functional groups are responsible for introducing the nitrogen to the diamond substrate by reacting to the “dangling” bond at the de-passivated site.

The nitrile group consists of molecules that contain the nitrile functional group that is bonded to a non-reactive group, consisting of any molecular structure that does not contain an additional reactive functional group. The non-reactive group may comprise, but is not limited to, a carbon chain of any length with any one or more of an alkane, alkene, alkyne or aromatic ring.

Similarly, the aziridine group consists of molecules that contain the aziridine functional group that is bonded to a non-reactive group. The non-reactive group comprises a three-membered heterocycle with one amine and two methylene bridges, but can also contain any other molecular structure that is not an additional reactive functional group.

While the above examples relate to a reactive group attached to a non-reactive group which is then removed, other examples may use other molecules. For example, the method may use slightly more complex molecules, such as to engineer the reaction such that the tail of the molecule breaks in a particular way (e.g., to leave two ¹³C atoms bound to the nitrogen, but everything else is removed). This may involve molecules with more heteroatoms in it. In other words, there may be one or more extended functional groups that support ¹³C doping. Further, there may be molecules that are potentially more industrially scalable. That is, the nitrile group may not be the only part of the molecule that remains bonded to the surface. For example, there may be extended groups that support ¹³C doping.

In a sense, it can be said that there are competing reactions such that the nitrogen in the reactive nitrogen group bonds favourably to the diamond than to other atoms in the nitrogen containing compound. This may comprise all nitrogen containing compounds that form a substituted or unsubstituted nitrogen containing aromatic group.

As stated above, the nitrogen containing compound may comprise one, two or more aromatic rings. For the double ring example, the nitrogen containing compound may comprise a three-fold coordinated nitrogen, i.e., nitrogen is bonded to three carbon atoms from the carbon surface. This can provide adsorption stability. Further, the nitrogen containing compound may comprise a nitrogen that forms a chemically stable lone electronic pair. Such a pair is useful for the formation of a nitrogen-vacancy. More particularly, the lone pair hinders further binding of N to additional elements, which enhances the pairing of N and the vacancy and thus supports the formation of the nitrogen vacancy. Further, the nitrogen containing compound comprises a nitrogen lone pair that is practically aligned in a predictable direction, which is achieved by bond angles involved in a three-fold coordination.

The nitrogen containing compound may have 3 or 4 double carbon bonds in the molecule, providing low energetics for adsorption onto the diamond surface, with high surface coverage. In some examples, a double bond adsorbs on the surface efficiently, in contrast to single bonds. The latter are used with bond breaking, a highly energetic process that may limit adsorption. The nitrogen containing compound may Contain 5 or 6 carbon member rings, as those are naturally observed in diamond, and facilitates the over-growth process for incorporation of the nitrogen into the diamond surface. The nitrogen containing compound may be an aromatic compound and may comprise cyclic resonances, which stabilise and maintain the lone pair electronic state of nitrogen. The lone pair electronic state of nitrogen facilitates the formation of N-V pairs by preventing additional bonding of nitrogen to carbon atoms during the overgrowth process. The nitrogen in the nitrogen containing compound may be part of a 5-member ring as those provide the largest known resonance for the stabilisation of a lone pair electronic state.

An identified candidate via modelling and theoretical search, validated by computational chemistry is indolizine. Indolizine is a heterocyclic compound with the formula C₈H₇N. It is an isomer of indole with the nitrogen located at a ring fusion position, which means the nitrogen in the indolizine forms a reactive nitrogen group. Indole is a heterocyclic aromatic compound consisting of a pyrrole ring (5-member ring) joined with a benzene ring (6-member ring). This compound is highly stable and found in several natural products, which is an advantage for industrial use. This means indolizine may support processes that are scalable to industrial scale so that a large number of devices can be manufactured using existing manufacturing hardware. In some examples, indolizine is used for incorporating nitrogen into a {111} diamond surface. However, in other examples, indolizine is used for incorporating nitrogen into a {100} diamond surface.

Indolizine forms a class of compounds, it comes either of
(1) Pure form with two member rings (Pyrrole and benzene)
(2) With an additional attachment on the 5-member pyrrole ring
(3) With an additional attachment on the 6-member benzene ring

The process involving (1) is identified as the most effective option. Pure indolizine is commercially available and provides a path to the process. In one example purity is at least 95%. However, in case the unidentified contaminants are detrimental to the usage of this compound, option (3) opens a large class of compounds that are found commercially with very high purity.

Additionally, the ligand attached to the 6-member ring may be a group found in the CVD growth chamber, to avoid uncontrolled secondary reactions for the overgrowth process, and may contain hydrocarbons. In some examples, the ligand comprises the following:
(1) Alkyl substituents (CH₃, C₂H₅, C₃H₇, C₄H₉, . . . ) attached to indolizine 6-member ring, with specific identified example of 2-tert-Butyl-indolizine, 5,8-Dimethyl-indolizine
(2) Aryl substituents (—C₆H₅X), 5-methyl-2-phenyl-indolizine

Halogen groups may also provide a viable route with —F, —Cl, —Br, —I groups such as:
(1) 7-Bromo-indolizine
(2) 7-Chloro-indolizine
(3) 7-(Bromo-methyl)-indolizine
(4) 7-(Chloro-methyl)-indolizine

FIG. 11 illustrates some examples of commercially available indolizine derivatives, including halogen substituents, alkyl substituents and aryl substituents. For example, 5-methyl-2-phenylindolizine and 2-tert-butyl-indolizise are available from Molport (molport.com) and 7-bromo-indolizine is available from Biosynth (biosynth.com).

The above reactive nitrogen groups, including nitrile, aziridine and indolizine molecules and others envisaged herein, are useful, as they can adsorb to the surface of the diamond substrate in a desired orientation relative to the surface. This desired orientation is one that is compatible with the subsequent CVD overgrowth, such that the molecule is orientated to have a similar geometric and chemical resemblance to the diamond structure in the overgrowth. More specifically, for the example of the {100} surface, the desired orientation is one, such that there four sp3 bonds across two adjacent surface dimers. These bonds establish strong adsorption of the nitrogen-containing compound to the diamond substrate, allowing it to withstand the volatile conditions of the subsequent diamond overgrowth.

The {111} surface may not exhibit dimers. Rather it is a 1×1 reconstruction. The surface geometry is such that there is a regular honeycomb pattern with hexagons formed between three adjacent surface and three adjacent subsurface carbon atoms. Consequently, the HDL patch on the {111} surface is a triangle formed from the three surface atoms, not a rectangle like on {100}, because of the different surface geometry. As shown in FIG. 4b, the triangular patch should be fabricated across the surface carbons of a single hexagon, instead of across three adjacent hexagons, in order to prevent crystal twinning in the subsequently overgrown layer. For {111}, the adsorbed unit forms sp3-bonds with the depassivated surface carbons. The resulting structure resembles a new diamond subunit formed on the triangular patch.

Once the nitrogen from the reactive nitrogen group adsorbs to the de-passivated site, the unwanted or undesired non-reactive group may be removed by processes, such as post-exposure heating of the diamond sample or exposure to reactive gases. The bond between the nitrogen and the carbon atom at the de-passivated site is sufficiently strong to withstand the temperature of the post-exposure heating. This temperature is also sufficiently high to break the bond between the reactive nitrogen group and the non-reactive group, causing the unwanted and undesired part of the nitrogen-containing compound to be removed. This leaves just the nitrogen adsorbed to the diamond substrate at the de-passivated site.

In the case of {100} diamond, a combination of X-ray photoelectron spectroscopy (XPS) and near edge X-ray absorption fine structure (NEXAFS) experiments have determined that hydrogen provides an effective resist for adsorption of acetonitrile at room temperatures (c.f., Step 3 as illustrated in FIG. 2c).

FIG. 9 illustrates XPS scans of the cleanly terminated diamond surface following exposure of 1000 Langmuirs of acetonitrile at room temperature and subsequent thermal processing. FIG. 9 also illustrates XPS data for the Nitrogen 1s (N1s) core level following acetonitrile exposure. Experimental work has further demonstrated chemical adsorption of acetonitrile to a partially-de-passivated H—C {100} surface at room temperature and exposure of 1000 Langmuirs. Spectra are taken both at room temperature and following annealing at higher temperatures.

These results demonstrate that nitrogen atoms remain bonded to the surface up to 900 C. This indicates strong chemical bonding on the same order as C—H surface bonds on the {100} surface of the diamond substrate, which undergo thermal desorption at approximately 850 C. Note that these temperatures are also roughly commensurate with sample temperatures during CVD growth. Adsorption of acetonitrile occurs on surfaces with completely de-passivated C—C dimers (produced via thermal desorption of hydrogen) as well as partially de-passivated C—C dimers produced via x-ray exposure. Further angle-resolved NEXAFS measurements demonstrate the presence of two clear peaks, suggesting that chemical adsorption rather than physisorption of acetonitrile has occurred. More specifically, clear angle-resolved peaks in N K-edge NEXAFS mean that there is an ordered alignment of some sort of nitrogen bond (presumably in this case to carbon). By itself this may not mean that there is chemical adsorption. However, for a molecule like acetonitrile, ordered alignment is not expected unless the nitrogen is directly bound to the substrate, because otherwise it would move and have a weaker (or no) angular dependence.

The bonding arrangement of the adsorbate can be verified in-situ using the STM in imaging mode by comparing with simulated images. Different adsorption configurations produce distinct STM images which have been simulated using ab initio techniques. If less desirable configurations are identified, selective means of removal can be used to remove the adsorbed molecule, including selective thermal desorption and resonant optical or electrical techniques (e.g., atomic-precision lithography using STM). Regardless, the desired result of lithography is to reproduce the cleanly-depassivated patch. This allows Step 3 to be repeated to obtain the desired adsorption geometry.

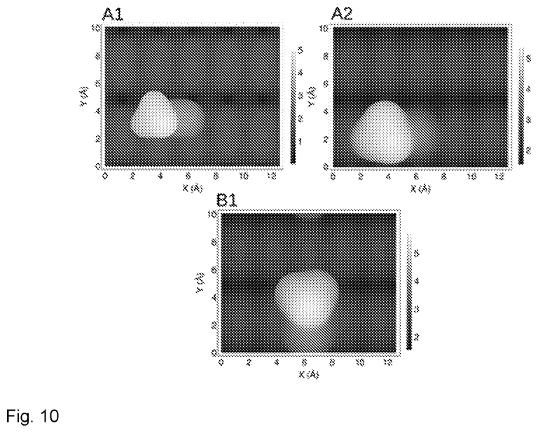

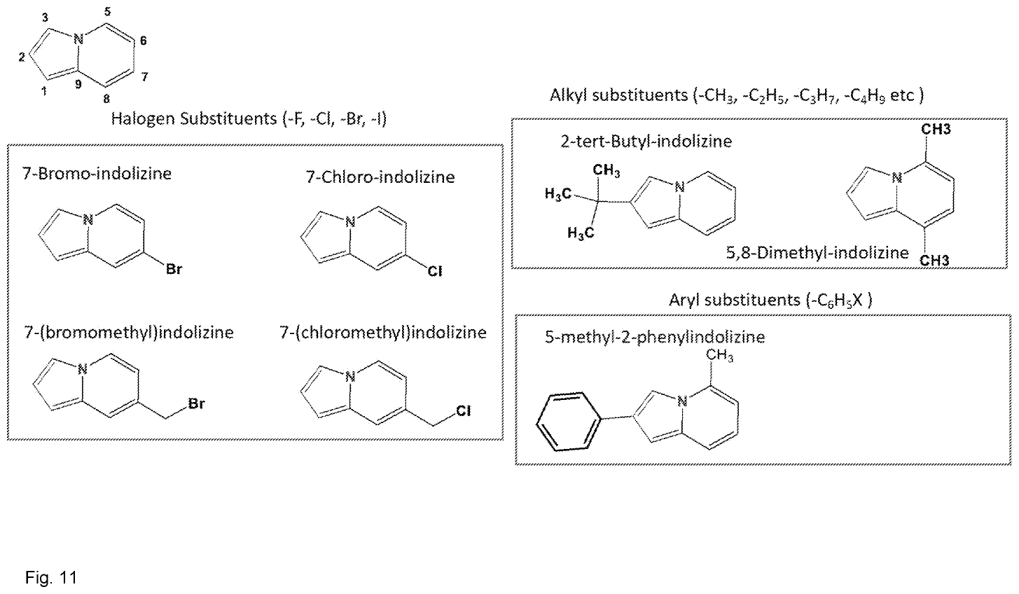

FIG. 10 illustrates simulated constant current (approximately 5 nA) STM images of the acetonitrile adsorbate in the A1, A2, and B1 configurations. These images demonstrate that it is possible to discern between the three different configurations based on the orientation of the adsorbate. The adsorbate can be seen to be either parallel (A1, A2) or perpendicular (B1) to the dimer rows. Calculations were performed using best standard practices of ab initio and STM theory. Simulations were performed using density functional theory with the Vienna Ab-initio Software Package (VASP). We employ Perdew-Burke-Ernzerhof (PBE) exchange-correlation functionals, a plane-wave basis with a 600 eV energy cut-off, and optimise ionic geometry up to a force cut-off of 0.05 eV/Å. The diamond surface is simulated using a periodic slab geometry with dimensions 5×4×6 (in units of bulk-diamond primitive unit cells). Chen's derivative rule is used to simulate STM images assuming a tip of s-like character.

### Step 4: N Encapsulation via Diamond Overgrowth

The goal of Step 4 (item 154 in method 150) is to encapsulate the adsorbed nitrogen atom within diamond to realise a bulk substitutional N defect or aligned NV centre. At minimum 50 nm of diamond overgrowth is used to obtain bulk-like NV properties. Here, diamond is overgrown in order to encapsulate the surface nitrogen, without causing either migration or desorption. The amount of overgrowth is dependent on the specifics of the desired optical and electronic control elements of a quantum computing device, which depending on design are placed at different distances and in specific geometry to the NV centres.

At present there are two proposed methods for encapsulating the adsorbate in bulk diamond. The first method employs CVD growth under specialised conditions to minimise the probability of desorption. The second method employs a carbon source and controlled sample conditions under UHV to produce a molecular beam epitaxy (MBE) diamond grown encapsulation layer several atoms thick. This then protects the adsorbate from desorption in a subsequent CVD overgrowth step. Both methods will now be discussed:

### Specialised CVD Overgrowth

Specialised CVD overgrowth is divided into three distinct stages, a pre-growth surface preparation stage, the specialised growth stage, and a bulk growth stage. It is noted here that the gases used in CVD include a carbon source, such as methane, and hydrogen. Hydrogen is included because it selectively etches off surface hydrogens and non-diamond carbon. The gases are ionized into chemically active radicals in the growth chamber using microwave power, a hot filament, an arc discharge, a welding torch, a laser, an electron beam, or other means. In order to prevent desorption of the adsorbed molecule, growth conditions are first used which result in a lower rate of sample etching, for example by increasing the growth inducing (i.e. carbon containing) gas species, to protect the N defect by encapsulating it in several atomic layers of diamond. More specifically, it is possible that the process uses an unusually high abundance of highly volatile carbon species. This means, the method uses a ratio of reactive carbon/growth species to reactive hydrogen/etch species that leads to diamond growth while avoiding the desorption of nitrogen. Avoiding desorption or diffusion in this context means that a suitable number of nitrogen atoms remain in the diamond crystal for use as a quantum device. This means that some nitrogen atoms may still desorb or diffuse and become unusable, but other nitrogen atoms remain in the diamond to result in a usable quantum device. It is also possible that a desired yield can be achieved by discarding some diamonds or discarding some areas in one diamond that have insufficient nitrogen atoms present, that is, too many nitrogen atoms desorbed or diffused from their intended location. Once hydrogen has been desorbed from the diamond surface in the intended areas and the nitrogen containing species have adsorbed to those areas, it is undesirable that the nitrogen containing species become mobile (desorb=depart the diamond surface into vacuum (z), or diffuse-travel away from the site on the surface (x, y)).

Following encapsulation, conventional CVD is used to grow more diamond so that the substitutional defect or NV centre is sufficient far from the surface to stabilise its properties and to form integrated control structures for device operation.

### Surface Preparation

Surface coating with carbonaceous/hydrocarbon species, for protecting the adsorbate during early-stage plasma ignition (and providing a time-limited carbon-rich source for the plasma during early-stage growth).

### Specialised Growth Stage

TABLE 1
Options which can be used in combination to encapsulate the adsorbed
nitrogen without desorption during the specialised growth stage.

| Option | Description |
|---|---|
| 1 | Specific early-stage growth recipe for minimizing adsorbate etching, |
| | including: high carbon (greater than 5% concentration), very low pressure |
| | (below 40 Torr; for example between 20-40 Torr; for example between |
| | 30-40 Torr), very low sample temperature (below 750 C.; for example |
| | between 500-750 C.; for example between 700-750 C.; for example |
| | between 400-600 C.). |
| 2 | Modified plasma geometry, through specific plasma conditions (very low |
| | pressure), modified stage position (height), modified sample holder with a |
| | recess having a depth between the range of 0.5 mm and 10 mm, and/or |
| | addition of new elements—such as a sample faraday cage—to control the |
| | ratio of active plasma species during the first few layers of diamond |
| | growth. It may be desirable to control the distance between the sample |
| | surface and the region where the plasma is heated by the microwaves. It |
| | can also be achieved by encapsulating the sample in a metal faraday cage |
| | (the microwave-heated region then has a boundary at the cage) and |
| | mounting the sample on a post within the cage. The Faraday cage is |
| | sufficiently large, greater than 4 mm, to encompass the sample, while also |
| | providing a sample surface to cage distance within the range of 0.5 mm to |
| | 10 mm. The pitch of the cage mesh is smaller than the wavelength of the |
| | microwave employed in the CVD. An example cage that may be suitable |
| | is provided in Aaqil Rifai, Daniel Creedon, Nhiem Tran, Maryam Hejazi, |
| | David Garrett, Andrew D. Greentree, Elena Pirogova, Alastair Stacey, |
| | Kate Fox, Highly uniform polycrystalline diamond coatings of three- |
| | dimensional structures, Surface and Coatings Technology, Volume 408, |
| | 2021, 126815, ISSN 0257-8972, |
| | https://doi.org/10.1016/j.surfcoat.2020.126815, which is incorporated |
| | herein by reference. |
| 3 | Use of a sample cage to block direct exposure to the plasma. |
| 4 | Use of a sample heater, to set the sample temperature prior to plasma |
| | ignition. |
| 5 | Use of a sample shutter, to enable the plasma growth conditions to be |
| | stabilized prior to sample exposure. |
| 6 | Growth of a second layer, on top of the initial nitrogen MBE diamond |
| | capping layer, incorporating dopants, such as phosphorus, to aid in |
| | nitrogen to NV conversion, which may be later removed and replaced |
| | with an intrinsic layer. |

The very low pressure and very low sample temperature of the specialised growth stage results in the preservation of the covalent bond between the carbon atom at the de-passivated site and the incorporated nitrogen. More specifically, the low pressure can lead to a relatively low abundance of atom removal (etching) species, such as atomic hydrogen, and the low sample temperature decreases the reactivity of the surface atomic species with atomic hydrogen.

### Bulk Overgrowth

The method uses conventional plasma conditions to produce bulk CVD diamond growth chosen to minimize NV-->NVH conversion, due to hydrogen diffusion into the crystal.

### In-Situ Growth of MBE Diamond Capping Layer

This process aims to achieve growth of a thin (<5 nm) MBE diamond capping layer under ultra-high vacuum (UHV) conditions, enabling encapsulation immediately following Step 3, in such a way that there is minimal surface etching. This may be achieved by:
1. Producing hydrocarbon (typically a lightweight hydrocarbon, such as methane) and hydrogen radicals in the UHV chamber using either thermal cracking or a microwave cavity.
2. Exposing the sample to a controlled flux of hydrocarbon and hydrogen radicals.
3. Controlling the sample temperature in such a way as to allow a reaction between the surface and the hydrocarbon radicals which favours the growth of sp³ carbon on the surface, with the hydrogen radicals acting to facilitate such a reaction. The sample temperature may be within the range of 300 C and 650 C to prevent acetonitrile desorption and less than 1200 C to prevent graphitisation.
4. Following this growth, the sample may be transferred to other fabrication systems (such as conventional CVD) for further processing.

As set out above, Chemical vapour deposition (CVD) is a growth technique for both {100} and {111} surfaces where the diamond sample is exposed to a hot plasma of atomic hydrogen and hydrocarbon radicals. In general, the stability of the adsorbate increases with the number of chemical bonds to the surface. The A2 structure possesses the maximum number of stable bonds to the surface possible and possesses a geometry similar to new-layer growth during CVD (c.f., FIG. 6 and FIG. 7). It is therefore considered the most viable adsorbate for atom-scale fabrication on the {100} surface. Similarly, in the case of {111} diamond the molecular adsorbate resembles new surface growth on the {111} surface (c.f., FIG. 6a-FIG. 6c).

There are two primary desorption mechanisms during CVD, thermal desorption and beta-scission. In general, the probability of thermal desorption increases with temperature. Low-temperature CVD growth may therefore be a viable option for mitigating thermal desorption. Beta-scission occurs when it is energetically favourable for migration of a surface electron to an adsorbed species, which then stimulates desorption.

Both the sample temperature and the pressure are sufficiently low during CVD growth to control the diamond growth rate and ensure the nitrogen defect does not migrate or desorb from the diamond. The temperature affects the diamond growth rate as an increase in temperature will increase the thermal energy of the system, thereby increasing the kinetic energy of the radicals in the CVD plasma. If the kinetic energy of a radical is greater than the binding energy of covalent bond between the nitrogen and the carbon on the diamond surface, the covalent bond can break and the nitrogen will desorb from the surface. The pressure affects the diamond growth rate as an increase in pressure changes the number of created radicals and therefore the probability of carbon radicals being in close enough proximity to bond and form the diamond structure. A low pressure can reduce the probability of radicals bombarding the nitrogen bonded to the diamond surface and can prevent the transfer of kinetic energy to preserve the covalent bond.

Growth on the {100} and {111} surfaces is typically realised through step-flow modes, characterised by the rate of layer growth exceeding the rate of nucleation. For both {100} and {111} surfaces, the presence of nitrogen enhances the rate of step-flow growth through nucleating new growth planes. On {111} surfaces, this is believed to be caused by the stability of surface-bound nitrogen to beta-scission. CVD growth on the {111} surface is also known to result in preferentially aligned NV centres, with recent work demonstrating near perfect alignment (99%). It is noted that “preferentially aligned NV” is defined as their defect axes are collinear and the defect axis is defined as the direction between the nitrogen and the vacancy site.

UHV-based methods of thin film diamond growth can be applied on materials such as silicon, by exposure of samples to controlled fluxes of hydrocarbon and hydrogen radicals. This approach relies on the increased chemical reactivity of radical species compared to their “standard” counterparts to allow alternative reaction pathways to those that would be observed in the conditions of a CVD reactor or atmospheric conditions, thereby allowing favourable growth of diamond via a MBE process. The low pressure of the UHV environment means that such radical species are capable of existing for long enough to be transported to the sample surface, while at higher pressures these reactive species would not exist for long enough to do so.

Various designs for UHV-compatible radical sources, including methyl (methane) radicals and hydrogen radicals are possible, and can either be purchased commercially or adapted from commercially available equipment. For example, a heated gas flow tube may be used where the gas flow and temperature can be controlled. Commercial examples may include Focus EFM-H and CreaTec HLC. Such a source is a piece of add-on equipment that can be integrated into a UHV instrument. There are three relevant methods of radical production:
1. Thermal cracking of the gas molecules—that is to say, flowing the gas over a heating element which is at a temperature appropriate for “cracking” the molecule into reactive pieces.
2. Electron ionisation of the gas molecules.
3. Microwave excitation of the molecule.

Thermal crackers, which are the most common radical source for UHV experiments, typically create radicals through processes 1 and 2, as under UHV most heating elements also produce an electron flux due to thermionic emission. A microwave cavity-based approach to radical generation creates radicals via microwave excitation, similar to a CVD system.

Control over the radical flux reaching the sample is achieved by:
Controlled gas flow rate through the radical source, typically realised with a mass-flow controller on each gas line.
Controlled temperature of the heating element, as this changes the “cracking” rate and influences the rate of electron-related molecular ionisation (thermal cracker).
Employing a “suppressor” electrode element on the radical source, which can remove a proportion of the radicals before they reach the sample.

### Step 5: NV Creation via Ion Implantation and Annealing

Post-growth transformation of bulk substitutional nitrogen defects into aligned NV centres (item 155 in method 150).

The procedure for this step is as follows:
1. Localised clusters of vacancies can be produced in the vicinity of the bulk nitrogen defect through carbon ion irradiation. The energy of the ion irradiation is conditional on depth of the nitrogen. For example at 50 nm, the energy is approximately 50 keV.
2. Annealing at a temperature of above 600 C, such as at 1400 C, causes migration of vacancies. An NV centre is subsequently formed upon contact between a mobile vacancy and the static substitutional nitrogen defect.

There is a non-zero probability that the adsorbed nitrogen is converted into a NV centre instead of a substitutional nitrogen defect during CVD overgrowth. This means that in method 150, steps 154 and 155 are performed in the same fabrication step. Optical microscopy may be used to confirm the presence of NV centres instead of substitutional nitrogen defects following overgrowth prior to production of vacancies. In this case, Step 5 may be not performed.

The NV centres can be transformed into a NV⁻ via a charging process. This charging process may occur via an n-type donor region. The donor region may be introduced in Step 1 during the preparation of the diamond sample, or an additional n-type donor region may be introduced in Step 5 via ion-implantation or doped diamond growth. The n-type dopant in the diamond allows an external voltage to be applied across the NV centre, which changes the Fermi level position and charges the NV centre.

It will be appreciated by persons skilled in the art that numerous variations and/or modifications may be made to the above-described embodiments, without departing from the broad general scope of the present disclosure. The present embodiments are, therefore, to be considered in all respects as illustrative and not restrictive.

1. A method for manufacturing multiple optically addressable qubits in diamond, the method comprising:
providing a diamond substrate with a passivated surface;
removing passivation atoms from the passivated surface to create multiple de-passivated sites where the passivation atoms have been removed;
exposing the multiple de-passivated sites to a nitrogen-containing compound to adsorb nitrogen at the multiple de-passivated sites of the diamond substrate;
overgrowing the multiple de-passivated sites with diamond by chemical vapour deposition (CVD) at a diamond growth rate related to a temperature and a pressure, wherein diffusion or desorption of the nitrogen at the multiple de-passivated sites is avoided to incorporate the nitrogen into the diamond;
converting the incorporated nitrogen into multiple nitrogen vacancies; and
charging the multiple nitrogen vacancies with a negative charge.

2. The method of claim 1, wherein any one or more of the diamond growth rate, the temperature and the pressure is sufficiently low, to avoid diffusion or desorption of the nitrogen at the multiple de-passivated sites.

3. The method of claim 1 or 2, wherein the nitrogen at the multiple de-passivated sites is bonded to the diamond substrate by a covalent bond between the nitrogen and a carbon atom of the diamond substrate, the covalent bond being defined by a binding energy.

4. The method of claim 3, wherein any one or more of the diamond growth rate, the temperature and the pressure is sufficiently low to preserve the covalent bond.

5. The method of claim 3 or 4, wherein the relative rate of sample etching, controlled by sample temperature and reactive species, is significantly lower than the rate of growth, such that the nitrogen at the multiple de-passivated sites is not desorbed and does not diffuse prior to or during diamond overgrowth.

6. The method of any one of claims 3 to 5, wherein the covalent bond is a sp³ bond.

7. The method of any one of the preceding claims, further comprising encapsulating the nitrogen at the multiple de-passivated sites by a protective layer.

8. The method of claim 7, further comprising forming the protective layer by specialised chemical vapour deposition overgrowth, according to one or more option in Table 1.

9. The method of claim 7 or 8, further comprising forming the protective layer by molecular beam epitaxy.

10. The method of any one of the preceding claims, further comprising preparing the diamond substrate to create atomically smooth patches on the diamond substrate.

11. The method of claim 10, further comprising preparing the diamond substrate at a substrate surface misorientation angle relative to a nominal surface orientation, to create the atomically smooth patches.

12. The method of claim 10 or 11, wherein preparing the diamond substrate at the substrate surface misorientation angle comprises creating step edges that define the atomically smooth patches between adjacent step edges.

13. The method of any one of the preceding claims, wherein overgrowing the diamond comprises growing a crystal lattice from the step edges.

14. The method of any one of the preceding claims, wherein the substrate surface misorientation angle is between 0.1 and 3.4 degrees.

15. The method of any one of the preceding claims, wherein converting the incorporated nitrogen into a nitrogen vacancy comprises carbon ion irradiation and annealing.

16. A method for manufacturing multiple optically addressable qubits in diamond, the method comprising:
providing a diamond substrate with a passivated surface, wherein the diamond substrate includes a doped region to introduce delocalised charge carriers into the diamond substrate and/or provide grounding for injected carriers;
removing passivation atoms from the passivated surface to create multiple de-passivated sites where the passivation atoms have been removed, wherein removing of the passivation atoms comprises moving a tip of a scanning tunnelling microscope (STM) across the passivated surface at atomic precision and creating a pulsed voltage drop between tip and diamond surface to remove the passivation atoms;
exposing the multiple de-passivated sites to a nitrogen-containing compound to adsorb nitrogen at the multiple de-passivated sites of the diamond substrate;
overgrowing the multiple de-passivated sites with diamond;
converting the incorporated nitrogen into multiple nitrogen vacancies; and
charging the nitrogen vacancies with a negative charge.

17. The method of claim 16, further comprising preparing the diamond substrate to create atomically smooth patches on the diamond substrate.

18. The method of claim 17, wherein moving the tip of the STM further comprises imaging the passivated surface to locate the atomically smooth patches.

19. The method of claim 17 or 18, further comprising preparing the diamond substrate at a substrate surface misorientation angle relative to a nominal surface orientation, to create the atomically smooth patches.

20. The method of claim 19, wherein preparing the diamond substrate at the substrate surface misorientation angle comprises creating step edges that define the atomically smooth patches between adjacent step edges.

21. The method of claim 20, wherein overgrowing the diamond comprises growing a crystal lattice from the step edges.

22. The method of any one of claims 19 to 21, wherein the substrate surface misorientation angle is between 0.1 and 3.4 degrees.

23. The method of any one of claims 16 to 22, further comprising, after moving the tip of the STM and before exposing the de-passivated site to the nitrogen-containing compound, confirming the removal of the passivation atoms from the passivated surface using STM imaging.

24. The method of any one of claims 16 to 23, further comprising confirming the adsorption of the nitrogen-containing compound to the diamond substrate using STM imaging.

25. The method of claim 24, wherein confirming the adsorption of the nitrogen-containing compound further comprises confirming that the nitrogen-containing compound adsorbed to the diamond substrate has a desired orientation relative to the diamond substrate.

26. The method of claim 25, wherein
(a) the diamond substrate has a {100} surface and the desired orientation is an orientation relative to the diamond substrate that provides four sp³ bonds across two adjacent surface dimers; or
(b) the diamond substrate has a {111} surface and the desired orientation is an orientation relative to the diamond substrate that provides three sp³ bonds to three surface carbon atoms.

27. The method of claim 25 or 26, wherein the method further comprises desorbing, using STM, the nitrogen-containing compound from the de-passivated site upon confirming that the nitrogen-containing compound has an undesired orientation relative to the diamond substrate.

28. The method of any one of claims 16 to 27, wherein removing the passivation atoms by the STM is performed at a pressure between 1×10⁻¹¹ Torr and 1×10⁻⁹ Torr.

29. The method of any one of claims 16 to 28, wherein removing the passivation atoms by the STM further comprises current pulses ranging from 1 ms to 10 ms with voltages ranging from 2.7 V to 7 V and currents ranging from 1 nA to 50 nA.

30. The method of any one of claims 16 to 29, wherein overgrowing the de-passivated site with diamond is performed by chemical vapour deposition.

31. The method of any one of claims 16 to 30, wherein converting the incorporated nitrogen into a nitrogen vacancy comprises carbon ion irradiation and annealing.

32. A method for manufacturing multiple optically addressable qubits in diamond, the method comprising:
providing a diamond substrate with a passivated surface;
removing passivation atoms from the passivated surface to create multiple de-passivated sites where the passivation atoms have been removed;
exposing the multiple de-passivated sites to a nitrogen-containing compound comprising a reactive nitrogen group, to adsorb nitrogen from the reactive nitrogen group at the multiple de-passivated sites of the diamond substrate;
overgrowing the multiple de-passivated sites with diamond;
converting the incorporated nitrogen into multiple nitrogen vacancies; and
charging the nitrogen vacancies with a negative charge.

33. The method of claim 32, wherein the nitrogen of the reactive nitrogen group forms a bond with a carbon atom of the diamond substrate at the de-passivated site.

34. The method of claim 32 or 33, wherein the reactive nitrogen group is a functional group and is bonded to a non-reactive group.

35. The method of claim 34, wherein the non-reactive group comprises a hydrocarbon.

36. The method of claim 34 or 35, wherein adsorbing the nitrogen-containing compound at the de-passivated site further comprises removing the non-reactive group by post-exposure heating.

37. The method of claim 36, wherein post-exposure heating is performed at a temperature that
(a) preserves the bond between the carbon atom of the diamond substrate at the de-passivated site and the nitrogen of the reactive nitrogen group; and
(b) breaks the bond between the reactive nitrogen group and the non-reactive group.

38. The method of any one of claims 32 to 37, wherein the nitrogen-containing compound is a nitrile.

39. The method of any one of claims 32 to 37, wherein the nitrogen-containing compound is an aziridine.

40. The method of any one of claims 32 to 37, wherein the nitrogen-containing compound comprises an aromatic ring.

41. The method of claim 40, wherein the nitrogen-containing compound comprises a nitrogen atom bonded to three carbon atoms.

42. The method of claim 40 or 41, wherein the nitrogen forms a lone electronic pair.

43. The method of any one of claims 40 to 42, wherein the nitrogen containing compound comprises three or four double carbon bonds.

44. The method of any one of claims 32 to 43, wherein exposing the multiple de-passivated sites to the nitrogen-containing compound further comprises isotopic control of the adsorbed nitrogen to control a spin of the adsorbed nitrogen.

45. The method of any one of claims 32 to 44, wherein the nitrogen-containing compound comprises a 13C isotope and exposing the multiple de-passivated sites to the nitrogen-containing compound comprises doping of the diamond substrate with the 13C isotope.

46. The method of claim 45, wherein the 13C isotope in the diamond substrate forms a qubit.

47. The method of claim 45 or 46, wherein, when in use, the qubit formed by the 13C isotope performs quantum data operations and the nitrogen vacancies act as a quantum bus.

48. The method of any one of claims 32 to 47, further comprising confirming the adsorption of the nitrogen-containing compound to the diamond substrate using scanning tunnelling microscopy (STM) imaging.

49. The method of claim 48, wherein confirming the adsorption of the nitrogen-containing compound further comprises confirming that the nitrogen-containing compound has a desired orientation relative to the diamond substrate.

50. The method of claim 49, wherein the desired orientation is an orientation relative to the diamond substrate that provides four sp³ bonds across two adjacent surface dimers.

51. The method of claim 49 or 50, wherein the method further comprises desorbing, using STM, the nitrogen-containing compound from the de-passivated site upon confirming that the nitrogen-containing compound has an undesired orientation relative to the diamond substrate.

52. The method of any one of claims 32 to 51, further comprising preparing the diamond substrate to create atomically smooth patches on the diamond substrate.

53. The method of claim 41, further comprising preparing the diamond substrate at a substrate surface misorientation angle relative to a nominal surface orientation, to create the atomically smooth patches.

54. The method of claim 52 or 53, wherein preparing the diamond substrate at the substrate surface misorientation angle comprises creating step edges that define the atomically smooth patches between adjacent step edges.

55. The method of claim 54, wherein overgrowing the diamond comprises growing a crystal lattice from the step edges.

56. The method of any one of claims 53 to 55, wherein the substrate surface misorientation angle is between 0.1 and 3.4 degrees.

57. The method of any one of claims 32 to 56, wherein overgrowing the de-passivated site with diamond is performed by chemical vapour deposition.

58. The method of any one of claims 32 to 57, wherein converting the incorporated nitrogen into a nitrogen vacancy comprises carbon ion irradiation and annealing.
